(19) United States
(12) Patent Application Publication
(10) Pub. No.: US 2006/0024855 A1
(43) Pub. Date: Feb. 2, 2006

(54) Method for manufacturing display device and display device

(75) Inventor: Junichi Sano, Chino-shi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 11/123,018

(22) Filed: May 6, 2005

(30) Foreign Application Priority Data
Jul. 27, 2004 (JP) 2004-218955

(51) Int. Cl. H01L 21/00

(52) U.S. Cl. 438/34

(57) ABSTRACT

A method for manufacturing a display device, such as an organic EL display device including at least a first electrode film, a light-emitting film, and a second electrode film over a substrate, with less use of photolithography, includes patterning at least one of the films by laser etching.

### BACKGROUND

The exemplary embodiments relate to a method for manufacturing a display device, such as an organic electro luminescence (EL) display device, and more particularly a display device, for an improved etching process.

An organic EL display device has a fine structure in which a number of pixels each including an anode, a light-emitting film, and a cathode are arranged two-dimensionally on a substrate. The manufacturing process of the organic EL display device thus uses a plurality of highly accurate photolithography processes to pattern a number of thin films such as electrodes and wires. See Japanese Unexamined Patent Publication No. 2001-284609.

### SUMMARY

The photolithography process, however, needs a number of steps after depositing an object to be patterned, such as photoresist coating, resist pre-bake, pattern exposure, pre-development bake, development, post-bake, etching, ashing, resist stripping, and washing, resulting in higher cost of manufacturing facilities. In addition, a large amount of chemicals, deionized water, gas and the like needs to be used, leading to higher operation cost for materials, wastewater treatment and the like.

Accordingly, it is an advantage of the exemplary embodiments to provide a method for manufacturing a display device for allowing the manufacturing of a display device such as an organic EL display device with less use of photolithography, and to provide a display device.

In order to achieve the object described above, the exemplary embodiments provide a method for manufacturing a display device including at least a first electrode film, a light-emitting film, and a second electrode film over a substrate. The method includes patterning at least one of the films by laser etching.

Such a configuration allows the patterning of films each having a predetermined function, such as an electrode, wire, and light-emitting film, without using photolithography.

Preferably, the patterning is implemented for at least one of the first and second electrode films to form a pixel electrode. This can provide a display with a two-dimensional screen. With a transparent electrode as one electrode film and a non-transparent (preferably, reflective) electrode as the other electrode film, a bottom-emission or top-emission display can be formed.

The light-emitting film is preferably an organic EL film. This can provide an organic EL display device.

A method for manufacturing a display device according to the exemplary embodiments includes: forming a first electrode film on a substrate; patterning the first electrode film formed on the substrate by laser etching to form a plurality of pixel electrodes each having an edge part; forming an insulating film that isolates the pixel electrodes from each other and covers the edge part of each pixel electrode; forming a light-emitting film over each pixel electrode; and forming a second electrode over the light-emitting film.

Such a configuration allows the first electrode film to be formed by laser etching. In addition, the insulating film that covers the edge part of the electrode film can form the separation-wall structure, which can facilitate the deposition of the light-emitting film by ink jet.

In the forming of the insulating film, the insulating film is preferably formed to cover a rolled-up part (raised part) resulting from the laser etching and generated at the edge part of the pixel electrode. This can prevent non-uniform thickness of the light-emitting layer and a short circuit between the first and second electrode films.

The insulating film is preferably a separation-wall film defining a pixel region. This allows the use of a positioning structure (separation-wall film in a grid) for positioning droplets of a light-emitting film material discharged by ink jet.

The insulating film is preferably made of photoresist or silicon oxide. The photoresist can facilitate the patterning. The silicon oxide can provide higher insulation.

The light-emitting film is preferably an organic EL film. This can provide an organic EL display device.

### ADVANTAGES OF THE EXEMPLARY EMBODIMENTS

The exemplary embodiments can pattern thin films for a display device with no use or less use of photolithography, which includes a number of processes such as resist coating, pattern exposure, development, and etching.

Laser etching is used in cathode patterning without the use of inversely-tapered resist films called a cathode separator to be described below, used in a related art cathode-patterning process. This can eliminate adverse affects on light-emitting layers due to the cathode separator, thereby improving the performance and reliability of the display device.

### BRIEF DESCRIPTION OF THE DRAWINGS

FIGS. 1A to IF are process charts illustrating a manufacturing process of an organic EL display device according to an exemplary embodiment of the present invention;

FIG. 2 are schematics illustrating a pixel portion of the organic EL display device according to an exemplary embodiment of the present invention;

FIG. 3 schematically illustrates a related art configuration using a cathode separator; and

FIGS. 4A to 4C are schematics illustrating comparative examples of the differences between related art configurations and an exemplary embodiment of the present invention.

### DETAILED DESCRIPTION OF EMBODIMENTS

With reference to the appended drawings, a method for manufacturing a display device according to exemplary embodiments will be described below.

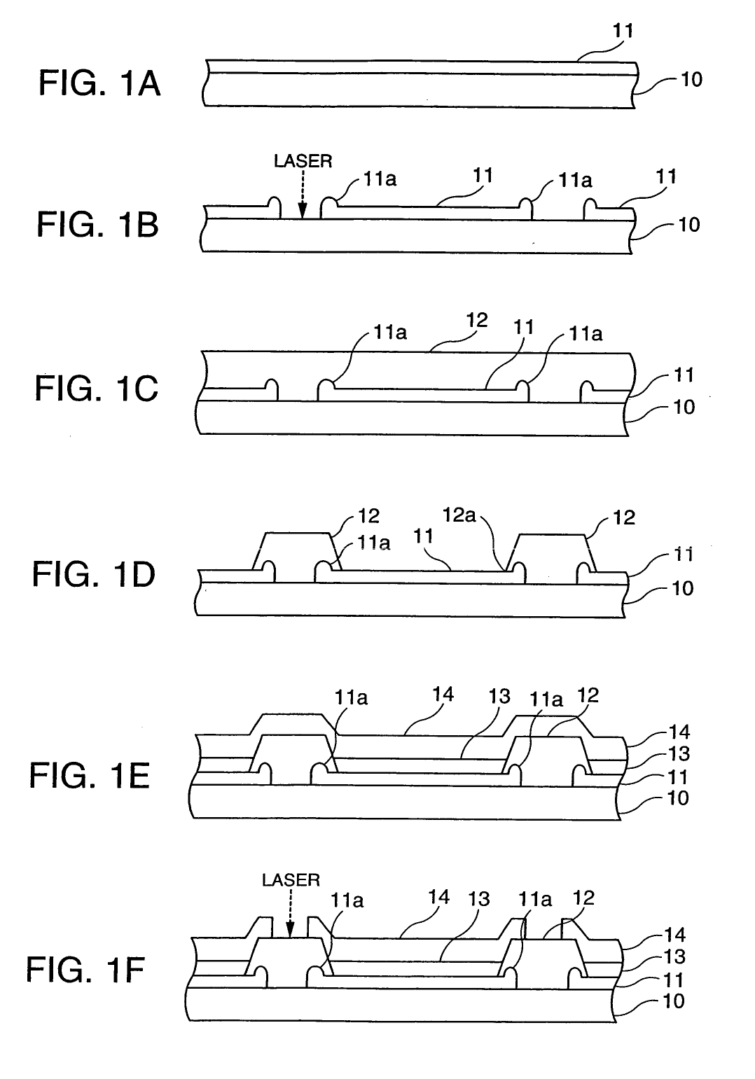

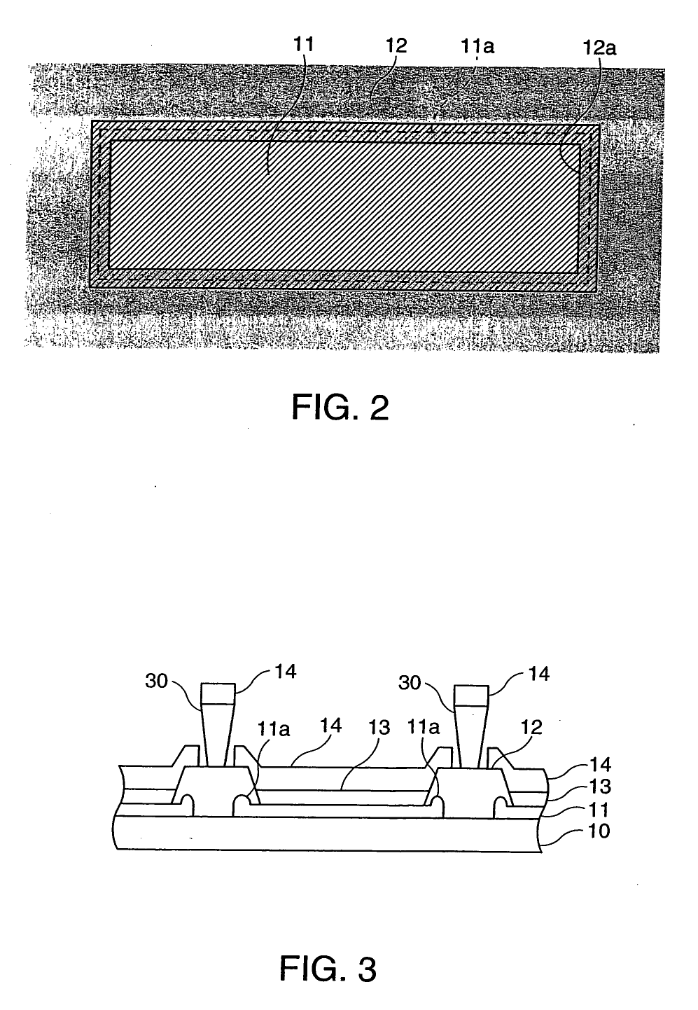

FIGS. 1A to 1F are schematics illustrating a manufacturing process of an organic EL display device according to the exemplary embodiments. FIG. 2 is a plan view schematic of a manufacturing step in the middle of the manufacturing process.

First, as shown in FIG. 1A, an indium tin oxide (ITO) film 11, which is a transparent electrode film, is deposited by a method such as sputtering with a thickness of about 0.2 μm over the whole surface of a glass substrate 10, which is a translucent substrate, or over the whole surface of an interlayer insulating film formed on components on the glass substrate, such as circuit wires and drive circuits.

As shown in FIG. 1B, the ITO film 11 is then patterned to form an anode of each pixel in the display. Laser etching (laser ablation) performs the patterning. More specifically, the etching is performed with a laser source for generating a laser beam, an X-Y stage that can mount the substrate 10 and move with it, and a control device for controlling the laser source and X-Y stage according to a pattern to be drawn. For example, the laser source can output a pulsed laser with a wavelength of 355 or 532 nm, a frequency of 100 kHz, a beam-spot diameter of 10 μm, and an average output of 1.0 W. The pulse energy is thus 10 μJ. The X-Y stage may move at 500 mm/sec with the beam spots overlapped by 5 μm to perform etching of line width of 10 μm to form an anode-electrode group for organic EL. Parts from which the ITO film 11 is removed by etching can provide sufficiently high insulation resistance.

Note that an edge of the anode 11 that is etched by laser has a rolled-up part 11a resulted from the thermal melting and buildup of part of the ITO film. For example, the laser etching under the above-described condition may cause the rolled-up part 11a with a height of about 0.1 μm and a width (in the direction from side to side in FIG. 11B) of about 1 μm.

As shown in FIG. 1C, a separation-wall film 12 made of an insulating material for defining the pixel regions of the anode group is then formed on the substrate 10 with a thickness of about 2 μm by a method such as spin coating. The separation-wall film 12 may be made of photoresist (photosensitive acrylic resin) or silicon oxide.

As shown in FIG. 1D, the separation-wall film 12 is patterned to form the separation wall separating the pixel regions. For example, the photoresist is exposed and developed according to a separation-wall pattern to leave the separation-wall portion. The separation-wall pattern may be a pattern in which the above-described rolled-up 11a of the anode 11 is covered by the separation-wall portion and is not exposed outside the separation wall. Covering the rolled-up part 11a with the insulating separation-wall film 12 can provide uniform light-emitting films of organic EL and prevent the short circuit between the anode and cathode. For example, the separation wall 12 with a trapezoidal cross section may have the upper side of about 20 μm length. After the separation-wall pattern is formed, oxygen plasma may be used to perform lyophilic treatment on the ITO surface, and fluorine plasma may be used to perform lyophobic treatment on the separation-wall surface.

FIG. 2 is a schematic top view of the substrate in FIG. 1D. In FIG. 2, portions corresponding to those in FIG. 1D are given the same reference numerals. In FIG. 2, a textured region represents the separation-wall portion and a hatched region represents the anode 11. The anode 11 is exposed through an opening of the separation-wall portion. The anode 11 is formed in about 50×150 μm, for example. The rolled-up part 11a in the periphery of the anode 11 resides on the inner side of an edge (opening edge) 12a of the separation-wall film 12, thereby preventing the external exposure of the rolled-up part 11a.

Note that a lyophilic and insulating film may be formed between the ITO film 11 and separation-wall film 12. Examples of this film may include a silicon oxide film. By partially exposing the lyophilic film along the opening edge 12a of a pixel, droplets of a high molecular-weight light-emitting material discharged into the opening of the pixel by ink jet spread uniformly over the whole top surface of the pixel electrode 11, preventing the short circuit between the anode and cathode.

As shown in FIG. 1E, with using the separation-wall film 12 as a wall surrounding a pixel region, the ink jet process may then discharge a light-emitting film material over the anode 11 to form a light-emitting film 13 over each pixel region. Note that the light-emitting film can include a properly selected structure such as a one-layer structure (for, particularly, high molecular-weight material) or two-to-five layer structure (for, particularly, low molecular-weight material).

A cathode film (back electrode film) 14 is then formed over the light-emitting film 13. The cathode film 14 may be formed by depositing an aluminum film with a thickness of about 0.2 μm, by a method such as vacuum deposition that has less damage on the light-emitting film. An electron-injection layer made of calcium, lithium fluoride or the like may intervene between the aluminum film and the light-emitting film 13.

As shown in FIG. 1F, the aluminum film 14 is then patterned to form cathodes of pixels in the display. Laser etching performs the patterning. More specifically, the etching is performed with the same system and almost the same condition as in the above-described ITO film patterning, except laser average output. The laser average output is preferably about one-third of that used in the ITO film etching. It is because the laser etching with higher output may have damage on the separation wall, which is the underlying film, and the generated heat and emitted gas during the etching may have adverse affects on the light-emitting film. More specifically, the laser beam with a beam spot diameter of 10 μm preferably has a pulse energy of about 2 to 5 μJ.

In addition, the cathode needs to be patterned in an inert atmosphere excluding most of water and oxygen to prevent or reduce the degradation of the light-emitting layer.

Laser etching can pattern the cathode without forming a cathode separator 30 as shown in FIG. 3 in which portions corresponding to those in FIGS. 1A to 1F are given the same reference numerals. Various adverse affects on the light-emitting layer 13 given by the cathode separator 30 can thus be prevented or reduced. For example, the cathode separator 30 may cause non-uniform thickness of the light-emitting layer 13.

Note that the above description of the manufacturing process of the organic EL display device does not refer to components such as electrode wiring, circuit wiring, and drive circuit, but those can be formed in the same way as in a related art image-display circuit.

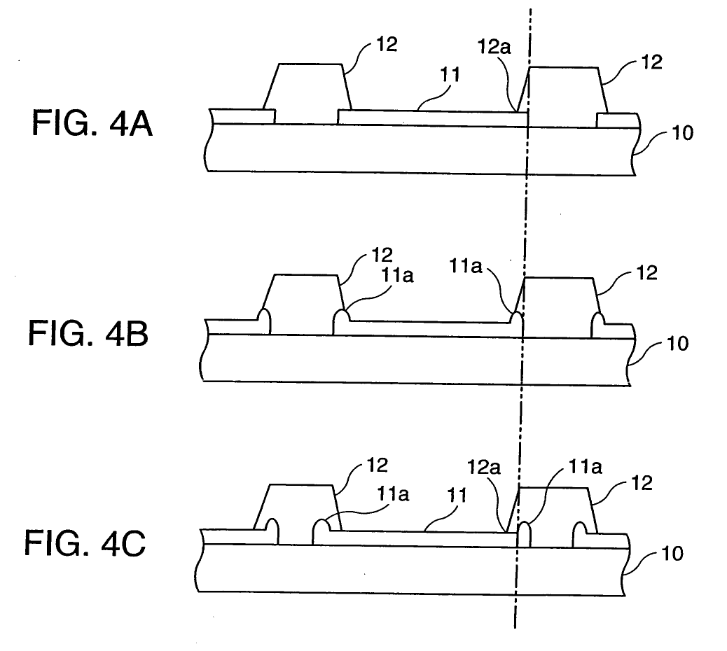

FIGS. 4A to 4C further illustrate the embodiment of the exemplary embodiments by using comparative examples. FIG. 4A shows the case where photolithography is used to manufacture a display device. FIG. 4B shows the case where laser etching replaces the photolithography to perform the manufacturing process. FIG. 4C shows the case where the shapes of separation-wall layers and pixel electrodes are determined in view of the rolled-up 11a of the pixel electrode 11.

As shown in FIG. 4A, the photolithography can be used to accurately etch the electrode film (ITO) 11. As shown in FIG. 4B, however, the laser-etching patterning using an electrode pattern (mask) usually used for the photolithography may expose the rolled-up part 11a outside the separation-wall film 12. As shown in FIG. 4C, the laser etching is therefore performed using the pattern of the pixel-electrode film made in terms of the rolled-up part 11a. The separation wall layer 12 can thus cover the rolled-up part 11a to secure insulation from the rolled-up part 11a.

In this way, laser etching can be used to pattern electrode films, with raised parts (rolled-up parts) of the films due to the laser etching being covered by an insulating film. Organic EL display devices can thus be manufactured with no use or less use of photolithography.

Note that in the above-described exemplary embodiment, the laser etching patterns two electrode films to form an anode and cathode for a unit pixel, but the cathode may be formed as a common electrode for each pixel, for example. The electrode film may also be patterned to form a cathode for each unit pixel, and an anode for each pixel may be formed as a common electrode.

In addition, the manufacturing method according to the exemplary embodiment uses a transparent electrode (ITO) and metal electrode as an anode and cathode, respectively, to provide a bottom-emission organic EL display device. Alternatively, the manufacturing method according to the exemplary embodiments may use a transparent electrode (ITO) and metal electrode as a cathode and anode, respectively, to provide a top-emission organic EL display device. In this case, the electrodes can be formed by depositing various types of materials, allowing more adequate setting of energy levels of films.

The manufacturing method according to the exemplary embodiments can apply to both a passive and active organic EL display device.

After the electrode is laser etched, processes such as chemical mechanical polishing (CMP) may planarize the electrode surface and remove rolled-up parts due to the laser etching.

What is claimed is:

1. A method for manufacturing a display device including at least a first electrode film, a light-emitting film, and a second electrode film over a substrate, comprising:
patterning at least one of the first electrode film, the light-emitting film, and the second electrode film by laser etching.

2. The method for manufacturing a display device according to claim 1, the patterning being implemented for at least one of the first and second electrode films to form a pixel electrode.

3. The method for manufacturing a display device according to claim 1, the light-emitting film being an organic electro luminescence (EL) film.

4. A method for manufacturing a display device, comprising:
forming a first electrode film on a substrate;
patterning the first electrode film formed on the substrate by laser etching to form a plurality of pixel electrodes each having an edge part;
forming an insulating film that isolates the plurality of pixel electrodes from each other and covers the edge part of each pixel electrode;
forming a light-emitting film over each pixel electrode; and
forming a second electrode film over the light-emitting film.

5. The method for manufacturing a display device according to claim 4, the forming of the insulating film including the insulating film being formed to cover a rolled-up part resulting from the laser etching and generated at the edge part of the pixel electrode.

6. The method for manufacturing a display device according to claim 4, the insulating film being a separation-wall film defining a pixel region.

7. The method for manufacturing a display device according to claim 4, the insulating film being made of photoresist or silicon oxide.

8. The method for manufacturing a display device according to claim 4, the light-emitting film being an organic EL film.

9. A display device, comprising:
a substrate;
an anode film;
an organic EL film; and
a cathode film over the substrate, the cathode film being patterned by laser etching.
